(19) United States
(12) Patent Application Publication
(10) Pub. No.: US 2026/0004043 A1
(43) Pub. Date: Jan. 1, 2026

(54) METHOD FOR EXTRACTING MODEL PARAMETER OF INTEGRATED CIRCUIT DEVICE, APPARATUS AND STORAGE MEDIUM

(71) Applicant: PRIMARIUS TECHNOLOGIES CO., LTD., Shanghai (CN)

(72) Inventor: Kai SHI, Shanghai (CN)

(21) Appl. No.: 19/114,694

(22) PCT Filed: Dec. 28, 2022
(86) PCT No.: PCT/CN2022/142568

§ 371 Date: Mar. 24, 2025

(30) Foreign Application Priority Data
Sep. 22, 2022 (CN) 202211156345.7

(51) Int. Cl. G06F 30/398

(52) U.S. Cl. CPC G06F 30/398

(57) ABSTRACT

A method for extracting a model parameter of an integrated circuit device, an apparatus and a storage medium. The method includes providing a test data set and a simulated data set for an integrated circuit device; providing a setting interface including a data checking list and a data extraction list; a user setting the data checking list of a setting interface; generating at least one data checking task on the basis of a user input setting, and performing rule checking on a test data set and a simulated data set according to a pre-stored data checking package, automatically marking, and generating one new target data set; a user setting the data extraction list of the setting interface and extracting parameters of one or more newly generated target data sets; and modeling according to the parameters extracted according to the data extraction list.

### TECHNICAL FIELD

The present disclosure relates to the technical field of computer aided design of integrated circuits, and in particular to a method for extracting a model parameter of an integrated circuit device, an apparatus and a storage medium.

### BACKGROUND ART

With the continuous development of semiconductor and integrated circuit technology, the importance of computer aided design (CAD) or electronic design automation (EDA) platform of integrated circuits is becoming more and more prominent. Model parameters for semiconductor devices fabricated in a particular integrated circuit process are extracted on the basis of some standard device model. After the model parameters are extracted, the various operating characteristics of the semiconductor device can be mathematically described in conjunction with a corresponding standard device model for use in device simulation during subsequent circuit design.

However, in the process of parameter extraction, there is a problem that part of the data does not comply with the rules or part of the simulation results do not meet the established requirements due to the measured data itself or the parameter modulation. In the actual parameter extraction process, data and sizes are often targeted and screened on the basis of human judgment or manual operations, adding labor and thus instability to the parameter extraction, while consuming a lot of time and effort.

### SUMMARY OF THE INVENTION

It is an object of the present disclosure to provide a method for extracting a model parameter of an integrated circuit device, an apparatus and a storage medium in view of the prior art.

Specifically, the method for extracting a model parameter of an integrated circuit device includes:
step S1: providing a test data set and a simulated data set for the integrated circuit device, wherein the test data set and the simulated data set include a plurality of test data obtained by testing the integrated circuit device under a plurality of groups of test conditions, wherein each group of test conditions includes a combination of a plurality of test conditions;
step S2: providing a setting interface, wherein the setting interface at least includes a data checking list and a data extraction list;
step S3: the data checking list receiving a user input, wherein the user input is configured for setting the data checking list of the setting interface;
step S4: generating at least one data checking task on the basis of a user input setting, performing a rule checking on the test data set and the simulated data set according to a pre-stored data checking package, marking automatically, and generating one new target data set;
step S5: the data extraction list receiving a user input, wherein the user input is configured for setting the data extraction list of the setting interface and extracting parameters of the one or more newly generated target data sets; and
step S6: modeling according to the parameters extracted according to the data extraction list.

Further, the data checking list includes a target data set name, a Device Marker and Checking Rule(s), and the Device Marker includes screening a target data set package after data marking; and the Checking Rule(s) include(s) a screening item that checks the detection data set and the simulated data set.

Further, the data extraction list includes a data marking pattern item; and the data marking pattern item includes four patterns, specifically including: extracting a data set pattern in which marker data is ignored, extracting a data set pattern in which selected marker data is ignored, extracting a data set pattern in which selected marker data is used, and extracting a data set pattern in which selected marker data and unmarker data are used.

Further, the user input being configured for setting the data checking list of the setting interface specifically in step S3 includes the user input being configured for selecting and setting the data checking list of the setting interface, and the user input being configured for selecting and setting the data checking list of the setting interface includes selecting and setting the Checking Rule(s);
the pre-stored data checking package in the step S4 includes a rule algorithm of a difference between simulated data and measured data and a rule algorithm of monotonicity;
the performing a rule checking on the test data set and the simulated data set according to a pre-stored data checking package in step S4 includes performing rule checking on data of the test data set and the simulated data set according to a rule algorithm in the pre-stored data checking package, the rule checking including detecting whether there is a difference between the test data set and simulated data set, and whether the test data set is monotonic; and
the generating one new target data set in step S4 includes an original test data set and a simulated data set, and marker data.

Further, the user input being configured for setting the data extraction list of the setting interface in step S5 specifically includes the user input being configured for selecting and setting the data extraction list of the setting interface, and the user input being configured for selecting and setting the data extraction list of the setting interface includes selecting a data marking pattern item and extracting parameters of one or more newly generated target data sets.

Further, the test data includes one or more of a trench trend curve, a current-voltage curve, and a capacitance-voltage curve.

Further, the integrated circuit device is a device selected from the group consisting of: a MOSFET transistor, an SOI transistor, a FinFET transistor, a BJT transistor, an HBT transistor, a TFT transistor, a MESFET transistor, a diode, a resistor or an inductor.

Further, a device model of the integrated circuit device is a device model selected from the group consisting of: BSIM3, BSIM4, BSIM6, BSIM-CMG, BSIM-IMG, BSIMSOI, UTSOI, HiSIM2, HiSIM_HV, PSP, GP-BJT or RPITFT.

Specifically, an electronic device includes: a memory for storing a processing program; a processor implementing the method for extracting a model parameter of an integrated circuit device according to any one item when executing the processing program.

In particular, a readable storage medium, wherein the readable storage medium has stored thereon a processing program which, when executed by a processor, implements the method for extracting a model parameter of an integrated circuit device according to any one item.

Advantageous effects of the present disclosure are as follows:

The method for extracting a model parameter of an integrated circuit device, apparatus and storage medium disclosed by the present disclosure realize automatic data division, and the data can be divided more accurately and the data quality is improved, which lays the foundation for the quality of device simulated data in subsequent circuit design and ensures the accuracy of simulation.

### BRIEF DESCRIPTION OF THE DRAWINGS

FIG. 1 is a schematic diagram of a rule checking provided by an embodiment of the present disclosure.

FIG. 2 is a schematic diagram of extracting parameters from a target data set provided in an embodiment of the present disclosure.

FIG. 3 is a schematic diagram of screening and ignoring selected marker data parameters provided by an embodiment of the present disclosure.

FIG. 4 is a schematic diagram of screening and using selected marker data parameters provided by an embodiment of the present disclosure.

FIG. 5 is another schematic diagram of screening and using selected marker data parameters provided by an embodiment of the present disclosure.

FIG. 6 is a flowchart diagram of a method for extracting a model parameter of an integrated circuit device provided in an embodiment of the present disclosure.

FIG. 7 is a schematic diagram of an embodiment of a computer device of the present disclosure.

### DETAILED DESCRIPTION OF THE INVENTION

Below, a more detailed explanation of the technical solution of the present disclosure will be provided in conjunction with the accompanying drawings. The present disclosure includes but is not limited to the following embodiments.

A method for extracting a model parameter of an integrated circuit device of the present disclosure can be used for various integrated circuit devices and corresponding device models. In some embodiments, the integrated circuit device is a device selected from the group consisting of: a MOSFET (metal oxide semiconductor field-effect transistor) transistor, an SOI (silicon on insulator) transistor, a FinFET (fin field-effect transistor) transistor, a BJT (bipolar junction transistor) transistor, an HBT (heterojunction bipolar transistor) transistor, a TFT (thin film transistor) transistor, a MESFET (metal-semiconductor field-effect transistor) transistor, a diode, a resistor or an inductor, etc.; the device model may be a device model selected from the group consisting of: BSIM3, BSIM4, BSIM6, BSIM-CMG, BSIM-IMG, BSIMSOI, UTSOI, HiSIM2, HiSIM_HV, PSP, GP-BJT or RPITFT. For example, for an MOSFET transistor, its corresponding device model may be BSIM3, BSIM4, BSIM6, or other known standard or non-standard models. The above-mentioned device models are merely exemplary, and in practical applications, a model corresponding to an integrated circuit device may be selected according to needs.

An MOSFET transistor is one of the most commonly used devices in an integrated circuit, and therefore in the following embodiments of the present disclosure, an integrated circuit device is exemplified as an MOSFET transistor. However, it will be understood by a person skilled in the art that the application of the present disclosure is not limited thereto.

In order to extract model parameters after selecting the appropriate device models, it is also necessary to provide test data corresponding to the integrated circuit device, which is typically obtained by testing the integrated circuit device under different test conditions. In some embodiments, the test conditions may be different dimensions of the integrated circuit device (e.g. different trench lengths, trench widths), different voltage bias conditions (e.g. a bias voltage Vbs between a body region and a source, different source and drain voltages Vds, etc.), or different temperature conditions, etc. Different types of test conditions may be combined into a new group of test conditions and the test conditions are used to describe the physical characteristics of the integrated circuit device under test and the test environment, such as the trench length, width, and bulk bias voltage of the device. It should be noted that the integrated circuit device described herein does not refer to a particular physical device, but refers to a generic term for a class of devices fabricated using the same integrated circuit process. For example, two integrated circuit devices fabricated using the same process and differing only in trench width may be considered the same integrated circuit device.

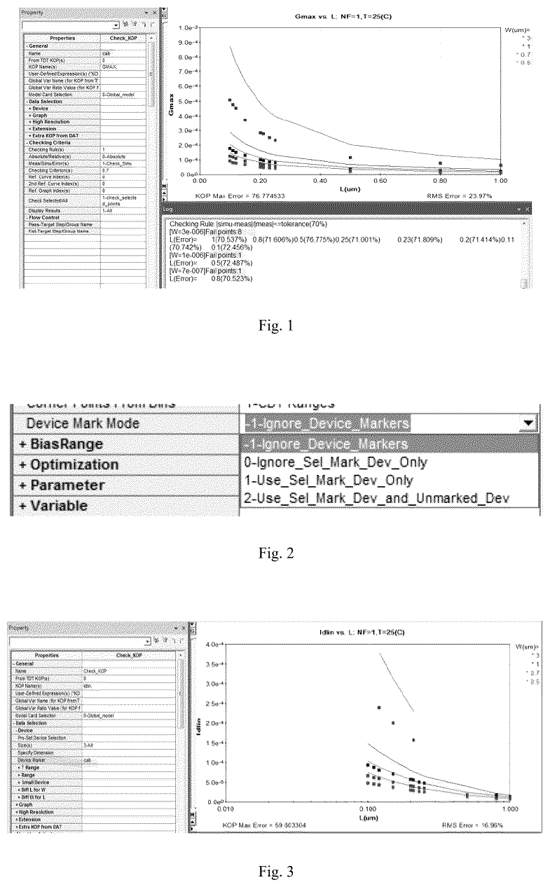

Testing the integrated circuit device under each group of test conditions may produce corresponding test data that may include, for example, one or more of a trench trend curve, a current-voltage curve, and a capacitance-voltage curve. In some embodiments, the test data may be trench trend curves, and accordingly, the test data set may include one or more trench trend curves. In other words, test data obtained under a plurality of groups of test conditions constitutes one test data set. In the embodiments described below, test data is used as an example of a trenching curve, but it will be understood by a person skilled in the art that in some other embodiments, the test data may be varied or adjusted according to the test conditions and test requirements under which the test is performed, and the present disclosure is not limited thereto. FIG. 1 includes a data checking list (Check APIs), which include a General, a Data Selection and a Checking Criteria.

The General includes a target data set name (Name) of the test data set and the simulated data set. The Data Selection includes a Device, wherein the Device includes a Device Marker.

Among them, the Checking Criteria includes Checking Rule(s), Absolute/Relative(s), Mess/Simu/Error(s), checking Criterion(s).

Table 1 shows some examples of the options in FIG. 1.

TABLE 1
Example of options

| Name of setting | Meaning of setting |
|---|---|
| General/Name | Indication of target data set name |
| Data Selection/Device/Device | Indication of the Device Marker, and screening of the |
| Marker | target data set package after data marking |
| Checking Criteria/Checking | Indication of the Checking Rule(s), screening items for |
| Rule(s) | checking of detection data set and simulated data set |

FIG. 2 shows a schematic diagram of extracting parameters from target data set. The data is marked after rule checking to form a target data set, and the target data set is extracted to include the screening mode in FIG. 2 as shown in Table 1, and the modeling is performed after the screening.

TABLE 1
Four patterns of extracting target data set

| [symbol] Extracting target data patterns | Meaning of extracting target data patterns |
|---|---|
| [symbol] -1-Ignore_Device_Markers | Definition of data set for extracting and ignoring |
| | marker data, generally default option |
| [symbol] 0-Ignore_Sel_Mark_Dev_Only | Definition of data set for extracting and ignoring |
| | selected marker data |
| [symbol] 1-Use_Sel_Mark_Dev_Only | Definition of data set for extracting and using |
| | selected marker data |
| [symbol] 2-Use_Sel_Mark_Dev_and_Unmarked | DevDefinition of data set for extracting and using |
| | selected marker data and unmarker data |

[symbol]

indicates data missing or illegible when filed

FIGS. 3-5 are schematic diagrams of screening marker data parameters provided by an embodiment of the present disclosure.

When the user needs to extract the data set in which the selected marker data is ignored in the cab target data set, the target data set cab is selected in the Device Marker in the Device in the Data Selection, and the 0-Ignore_Sel_Mark_Dev_Only option is selected and modeled, resulting in the schematic diagram as shown in FIG. 3.

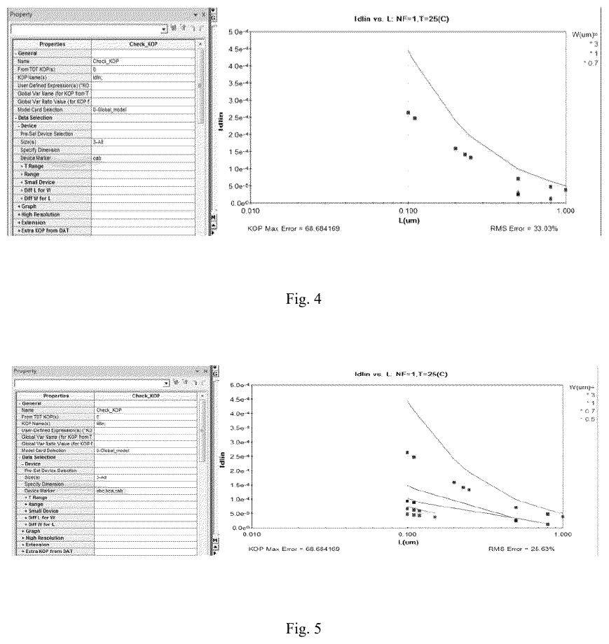

When the user needs to extract the data set in which the selected marker data is used in the cab target data set, the target data set cab is selected in the Device Marker in the Device in the Data Selection, and the 1-Ignore_Sel_Mark_Dev_Only option is selected and modeled, resulting in the schematic diagram as shown in FIG. 4.

When the user needs to extract multiple target data sets such as abc, bca and cab to use the selected marker data, the target data sets abc, bca and cab are selected from the Device Marker in the Device in the Data Selection, and the option of 1-Use_Sel_Mark_Dev_Only is selected and modeled, and the schematic diagram shown in FIG. 5 is obtained.

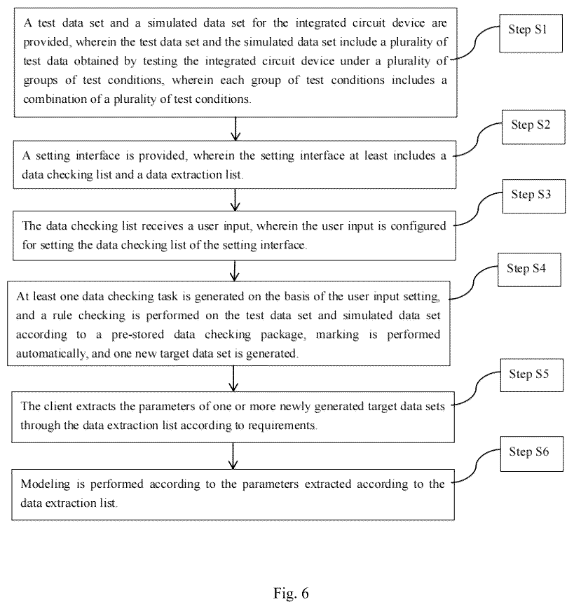

FIG. 6 is a flowchart diagram of a method for extracting a model parameter of an integrated circuit device provided in an embodiment of the present disclosure, including:
Step S1: A test data set and a simulated data set for the integrated circuit device are provided, wherein the test data set and the simulated data set include a plurality of test data obtained by testing the integrated circuit device under a plurality of groups of test conditions, wherein each group of test conditions includes a combination of a plurality of test conditions.

Among other things, the test conditions may be different dimensions of the integrated circuit device (e.g. different trench lengths, trench widths), different voltage bias conditions (e.g. a bias voltage Vbs between a body region and a source, different source and drain voltages Vds, etc.), or different temperature conditions, etc. Testing the integrated circuit device under each group of test conditions may produce corresponding test data that may include, for example, one or more of a trench trend curve, a current-voltage curve, and a capacitance-voltage curve. In the present embodiment, the test data includes a plurality of trenching curves, but it will be understood by a person skilled in the art that in some other embodiments, the test data may be varied or adjusted according to the test conditions and test requirements under which the test is performed, and the present disclosure is not limited thereto.
Step S2: A setting interface is provided, wherein the setting interface at least includes a data checking list and a data extraction list.

The data checking list (Check APIs) includes a General, a Data Selection and a Checking Criteria; the General includes the target data set name (Name) of the test data set and the simulated data set; the Data Selection includes a Device; the Device includes a Device Marker.

Among them, the Checking Criteria includes Checking Rule(s), Absolute/Relative(s), Mess/Simu/Error(s), and checkingCriterion(s). Step S3: The data checking list receives a user input, wherein the user input is configured for setting the data checking list of the setting interface. The user input of the present embodiment being configured for setting the data checking list of the setting interface includes inputting a setting and selecting a setting.

The input setting includes naming the target data set name for the data set subjected to the data checking, the specific setting position of the present embodiment is in the data checking list (Check APIs)-General-Name.

The selection setting includes a screening item representing Checking Rule(s) and checking the detection data set and the simulated data set, and the specific setting position of the present embodiment is in data checking list (Check APIs)-Checking Criteria-Checking Rule(s); in this embodiment, for example, in FIG. 1, the Checking Rule(s) is(are) checking a difference between the measured data set and the simulated data set, namely, the Checking Rule(s) is(are) selected and set as 1, and the specific implementation method includes but is not limited to the following algorithm of formula 1:

$$\vert simu - meas \vert / meas <= tolerance ( 70 \% ) \qquad Formula ( 1 )$$

Equation 1 indicates whether the measured data and the simulated data for the same trench width differ by less than or equal to a tolerance, e.g. 70%, for the same trench length.

The Checking Rule(s) is(are) not limited to checking the difference between the measured data set and the simulated data set, but also includes other Checking Rule(s) such as checking whether the data set is monotonic.
Step S4: At least one data checking task is generated on the basis of the user input setting, and a rule checking is performed on the test data set and simulated data set according to a pre-stored data checking package, marking is performed automatically, and one new target data set is generated, wherein the pre-stored data checking package includes a rule algorithm of a difference between simulated data and measured data and a rule algorithm of monotonicity, wherein performing rule checking on the test data set and simulated data set according to the pre-stored data checking package includes performing rule checking on the data of the test data set and simulated data set according to a rule algorithm in the pre-stored data checking package, the rule checking including detecting whether there is a difference between the test data set and simulated data set and whether the test data set is monotonic.

In FIG. 1 of the present embodiment, a red discrete point represents measured data with a trench width of 3 μm, and a red continuous curve represents simulated data with a trench width of 3 μm; the discrete points of blue represent measured data with a trench width of 1 μm, and the continuous curves of blue represent simulated data with a trench width of 1 μm; the discrete points of ink green represent measured data with a trench width of 0.7 μm, and the continuous curves of ink green represent simulated data with a trench width of 0.7 μm; and the pink discrete points represent measured data with a trench width of 0.5 μm and the pink continuous curves represent simulated data with a trench width of 0.5 um.

Formula 1 indicates whether the difference between the measured data and the simulated data of the same trench width is less than or equal to a tolerance value (tolerance) under the same trench length; if the test data is greater than the tolerance value, the difference between measured data and simulated data of the same trench width is too great under the same trench length and is the Fail data, the measured data greater than the still tolerance value is marked and returned to the Fail; if the test data is less than or equal to the tolerance value, i.e. the difference between the measured data and the simulated data of the same trench width is not large under the same trench length, it is Pass data, not marked and not returned. The marker data, the original measured data set and the simulated data set generate a new target data set.
Step S5: The data extraction list receives user input, wherein the user input is configured for setting the data extraction list of the setting interface and extracting parameters of the one or more newly generated target data sets.
Step S6: Modeling is performed according to the parameters extracted according to the data extraction list.

The user input being configured for setting the data extraction list of the setting interface specifically includes the user input being configured for selecting and setting the data extraction list of the setting interface, and the user input being configured for selecting and setting the data extraction list of the setting interface includes selecting a data marking pattern item and extracting parameters of one or more newly generated target data sets. It includes four patterns specifically: extracting a data set pattern in which marker data is ignored, extracting a data set pattern in which selected marker data is ignored, extracting a data set pattern in which selected marker data is used, and extracting a data set pattern in which selected marker data and unmarker data are used.

Therein, the schematic diagram of the screened marker data parameter modeling provided in Embodiment 1 is as shown in FIG. 3. In this embodiment, it is required to extract a data set in the cab target data set ignoring the selected marker data, and it can be understood that not all the marker data is required, and in this embodiment, it is required not to display the marker data selected by the client. Operations may be as follows: selecting the target data set cab from the Device Marker in the Device in the Data Selection, selecting marker data which does not need to be displayed, selecting 0-Ignore_Sel_Mark_Dev_Only option and modeling, and the schematic diagram as shown in FIG. 3 is obtained.

Therein, the schematic diagram of the screened marker data parameter modeling provided in Embodiment 2 is as shown in FIG. 4. In this embodiment, the data set using the selected marker data in the cab target data set needs to be extracted, and it can be understood that the present embodiment only needs to display the marker data selected by the client. The operations may be as follows: selecting the target data set cab from the Device Marker in the Device in the Data Selection, selecting the marker data to be used, selecting 0-Ignore_Sel_Mark_Dev_Only option and modeling, and the schematic diagram as shown in FIG. 4 is obtained.

The schematic diagram of parameter modeling of screened marker data provided in Embodiment 3 is as shown in FIG. 5. In the present embodiment, it is necessary to extract a data set of selected marker data from multiple target data sets such as abc, bca and cab, and it can be understood that the present embodiment only needs to display the marker data in the multiple target data sets selected by the client. Operations may be as follows: selecting a plurality of target data sets, such as abc, bca and cab, from the Device Marker in the Device in the Data Selection, selecting marker data required to be used, and selecting a 0-Ignore_Sel_Mark_Dev_Only option and modeling, and the schematic diagram shown in FIG. 5 is obtained.

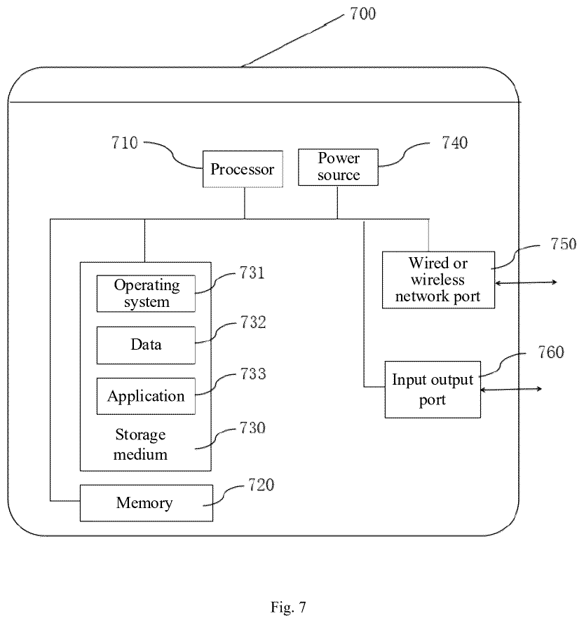

As shown in FIG. 7, on the basis of the same concept, the present disclosure also provides a computer device 700 that may vary widely in configuration or performance, and may include one or more central processing units (CPU) 710 (e.g. one or more processors) and memory 720, one or more storage media 730 (e.g. one or more mass storage devices) having stored thereon applications 733 or data 732. Here, the memory 720 and the storage medium 730 may be transient storage or persistent storage. A program stored on the storage medium 730 may include one or more modules (not shown), each of which may include a series of instruction operations on computer device 700. Furthermore, the processor 710 may be configured to communicate with a storage medium 730 to perform a series of instruction operations on the storage medium 730 on the computer device 700. The computer device 700 may also include one or more power sources 740, one or more wired or wireless network ports 750, one or more input output ports 760, and/or one or more operating systems 731, such as Windows Serve, MacOSX, Unix, Linux, FreeBSD, etc.

A person skilled in the art can understand that the computer device structure shown in FIG. 7 does not constitute a limitation on the computer device, and may include more or fewer components than shown in the diagram, or combine certain components or different component arrangements. The computer-readable instruction, when executed by the processor, causes the processor to perform the following steps when executing the computer-readable instruction: providing a test data set and a simulated data set for the integrated circuit device, wherein the test data set and simulated data set include a plurality of test data obtained by testing the integrated circuit device under a plurality of groups of test conditions, wherein each group of test conditions include a combination of a plurality of test conditions; providing a setting interface, wherein the setting interface at least includes a data checking list and a data extraction list; the data checking list receives a user input, and the user input is configured for setting the data checking list of the setting interface; at least one data checking task is generated on the basis of the user input setting, and a rule checking is performed on the test data set and simulated data set according to a pre-stored data checking package, marking is performed automatically, and a new target data set is generated; the data extraction list receives a user input, and the user input is configured for setting the data extraction list of the setting interface and extracting parameters of the one or more newly generated target data sets; modeling is performed according to the parameters extracted according to the data extraction list.

In one embodiment, a readable storage medium is presented, which, when executed by one or more processors, causes the one or more processors to perform the above-mentioned methods, and specific steps are not described in detail herein.

It can be clearly known by the skilled in the art that, for facilitating and simplifying the description, specific working processes of the above-mentioned system, apparatus and unit can refer to corresponding processes in the above-mentioned method embodiments so as to be no longer repeated herein.

Further, the integrated units, if implemented in the form of software functional units and sold or used as stand-alone products, may be stored in a computer-readable storage medium. Based on such an understanding, the technical solutions of the present disclosure, either per se or in part making a contribution to the prior art or in their entirety, may be embodied in the form of a software product, which computer software product may be stored in one storage medium, including instructions to cause one computer device, which may be a personal computer, a server, or a network device, to perform all or part of the methods of the various embodiment methods of the present disclosure. The storage medium described above may include: various media that may store program codes, such as a U-disk, a removable hard disk, a read-only memory (ROM), a random access memory (RAM), a magnetic or optical disk.

In summary, the above-mentioned embodiments are merely illustrative of the technical solution of the present disclosure, and are not restrictive. Although the present disclosure has been described in detail with reference to the foregoing embodiments, those skilled in the art will appreciate that the technical solutions disclosed in the above-mentioned embodiments can still be amended, or some of the technical features thereof can be replaced with equivalents. Such modifications and substitutions do not depart the substance of the corresponding technical solution from the spirit and scope of the technical solutions of the embodiments of the present disclosure.

1. A method for extracting a model parameter of an integrated circuit device, comprising:
step S1: providing a test data set and a simulated data set for the integrated circuit device, wherein the test data set and the simulated data set include a plurality of test data obtained by testing the integrated circuit device under a plurality of groups of test conditions, wherein each group of test conditions includes a combination of a plurality of test conditions;
step S2: providing a setting interface, wherein the setting interface at least comprises a data checking list and a data extraction list;
step S3: the data checking list receiving a user input, wherein the user input is configured for setting the data checking list of the setting interface;
step S4: generating at least one data checking task on the basis of a user input setting, performing a rule checking on the test data set and the simulated data set according to a pre-stored data checking package, marking automatically, and generating one new target data set;
step S5: the data extraction list receiving a user input, wherein the user input is configured for setting the data extraction list of the setting interface and extracting parameters of the one or more newly generated target data sets; and
step S6: modeling according to the parameters extracted according to the data extraction list.

2. The method for extracting a model parameter of an integrated circuit device according to claim 1, wherein the data checking list comprises a target data set name, a Device Marker and Checking Rule(s), and the Device Marker comprises screening a target data set package after data marking; and the Checking Rule(s) comprise(s) a screening item that checks the detection data set and the simulated data set.

3. The method for extracting a model parameter of an integrated circuit device according to claim 1, wherein the data extraction list comprises a data marking pattern item; and the data marking pattern item comprises four patterns, specifically comprising: extracting a data set pattern in which marker data is ignored, extracting a data set pattern in which selected marker data is ignored, extracting a data set pattern in which selected marker data is used, and extracting a data set pattern in which selected marker data and unmarker data are used.

4. The method for extracting a model parameter of an integrated circuit device according to claim 2, wherein the user input being configured for setting the data checking list of the setting interface specifically in step S3 comprises the user input being configured for selecting and setting the data checking list of the setting interface, and the user input being configured for selecting and setting the data checking list of the setting interface comprises selecting and setting the Checking Rule(s);
the pre-stored data checking package in the step S4 comprises a rule algorithm of a difference between simulated data and measured data and a rule algorithm of monotonicity;
the performing a rule checking on the test data set and the simulated data set according to a pre-stored data checking package in step S4 comprises performing rule checking on data of the test data set and the simulated data set according to a rule algorithm in the pre-stored data checking package, the rule checking comprising detecting whether there is a difference between the test data set and simulated data set, and whether the test data set is monotonic; and
the generating one new target data set in step S4 comprises an original test data set and a simulated data set, and marker data.

5. The method for extracting a model parameter of an integrated circuit device according to claim 3, wherein the user input being configured for setting the data extraction list of the setting interface in step S5 specifically comprises the user input being configured for selecting and setting the data extraction list of the setting interface, and the user input being configured for selecting and setting the data extraction list of the setting interface comprises selecting a data marking pattern item and extracting parameters of one or more newly generated target data sets.

6. The method for extracting a model parameter of an integrated circuit device according to claim 1, wherein the test data comprises one or more of a trench trend curve, a current-voltage curve, and a capacitance-voltage curve.

7. The method according to claim 1, wherein the integrated circuit device is a device selected from the group consisting of: an MOSFET transistor, an SOI transistor, a FinFET transistor, a BJT transistor, an HBT transistor, a TFT transistor, an MESFET transistor, a diode, a resistor or an inductor.

8. The method according to claim 7, wherein a device model of the integrated circuit device is a device model selected from the group consisting of: BSIM3, BSIM4, BSIM6, BSIM-CMG, BSIM-IMG, BSIMSOI, UTSOI, HiSIM2, HiSIM_HV, PSP, GP-BJT or RPITFT.

9. An electronic apparatus, comprising:
a memory configured for storing a processing program; and
a processor implementing the method for extracting a model parameter of an integrated circuit device according claim 1 when executing the processing program.

10. A readable storage medium, wherein the readable storage medium has stored thereon a processing program which, when executed by a processor, implements the method for extracting a model parameter of an integrated circuit device according to claim 1.
